(19) United States
(12) Patent Application Publication
(10) Pub. No.: US 2025/0311594 A1
(43) Pub. Date: Oct. 2, 2025

(54) DISPLAY DEVICE, METHOD OF MANUFACTURING THE SAME AND ELECTRONIC DEVICE INCLUDING THE SAME

(71) Applicant: Samsung Display Co., LTD., Yongin-si (KR)

(72) Inventors: SANGSHIN LEE, Yongin-si (KR); YEONJU KANG, Yongin-si (KR); SANGHOON KIM, Yongin-si (KR); JAESUK MOON, Yongin-si (KR); Yuri Lee, Yongin-si (KR)

(73) Assignee: Samsung Display Co., LTD., Yongin-si (KR)

(21) Appl. No.: 19/063,938

(22) Filed: Feb. 26, 2025

(30) Foreign Application Priority Data
Mar. 27, 2024 (KR) 10-2024-0041993

(51) Int. Cl. H10K 59/80; H10K 59/12; H10K 59/127

(52) U.S. Cl. CPC H10K 59/8723; H10K 59/1201; H10K 59/127; H10K 59/8792

(57) ABSTRACT

A display device includes a first substrate, a display element layer disposed on the first substrate, and including a plurality of pixels, a second substrate disposed on the display element layer, and facing the first substrate, a first spacer disposed between the display element layer and the second substrate, and extending to the display element layer and a second spacer disposed between the display element layer, and extending to the second substrate.

### CROSS-REFERENCE TO RELATED APPLICATION(S)

This application claims priority to and benefits of Korean Patent Application No. 10-2024-0041993 under 35 U.S.C. § 119, filed on Mar. 27, 2024 in the Korean Intellectual Property Office, the entire contents of which are herein incorporated by reference.

### BACKGROUND

### 1. Technical Field

Embodiments relate to a display device and a method of manufacturing the same. More particularly, embodiments relate to a display device in which a sealing member is formed on a substrate and a method of manufacturing the same.

### 2. Description of the Related Art

If impurities such as moisture or oxygen enter a display device from the outside, a lifespan of a transistor included in the display device may be shortened and a luminous efficiency of a light-emitting element may decrease.

Accordingly, the display device may be encapsulated to isolate an interior of the display device from the outside and prevent impurities such as moisture from penetrating. For example, the display device may include a substrate and an encapsulation substrate that forms a cover or cap on the substrate. The substrate and the encapsulation substrate may be coupled by a sealing member and a plurality of spacers.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with an improved durability.

Embodiments provide a method of manufacturing the display device.

A display device according to an embodiment may include a first substrate, a display element layer disposed on the first substrate, and including a plurality of pixels, a second substrate disposed on the display element layer, and facing the first substrate, a first spacer disposed between the display element layer and the second substrate, and extending to the display element layer, and a second spacer disposed between the display element layer, and extending to the second substrate.

In an embodiment, the second spacer may extend to the first spacer.

In an embodiment, the first spacer and the second spacer may be spaced apart from each other in a direction parallel to the first substrate.

In an embodiment, the second spacer may extend to the display element layer.

In an embodiment, a height of the second spacer may be greater than a height of the first spacer.

In an embodiment, a planar shape of the first spacer and a planar shape of the second spacer may be same.

In an embodiment, a planar shape of the first spacer and a planar shape of the second spacer may be different.

In an embodiment, the first spacer and the second spacer may be disposed between pixels adjacent to each other among the plurality of the pixels.

In an embodiment, the display device may further include a third spacer disposed between multiple ones of the first spacer adjacent to each other on the first substrate. The third spacer and the first spacer may include a same material.

In an embodiment, the third spacer may extend to the second spacer.

In an embodiment, the third spacer may not extend to the second spacer.

In an embodiment, a planar shape of the third spacer and a planar shape of the first spacer may be different.

In an embodiment, the second spacer may include an organic material.

In an embodiment, the second spacer may further include an inorganic material.

In an embodiment, the second spacer may further include a light-blocking material.

In an embodiment, the display device may further include a sealing member disposed on the first substrate, and surrounding at least a portion of each of the first spacer and the second spacer.

In an embodiment, a height of the sealing member may be greater than a sum of a height of the first spacer and a height of the second spacer.

A method of manufacturing a display device according to an embodiment may include forming a display element layer including a plurality of pixels on a first substrate, forming a first spacer on the display element layer, forming a second spacer corresponding to the first substrate on a second substrate facing the first substrate, and attaching the first substrate and the second substrate to each other.

In an embodiment, in the attaching of the first substrate and the second substrate to each other, the first substrate and the second substrate may be attached to each other so that the first spacer and the second spacer extend to each other.

In an embodiment, in the attaching of the first substrate and the second substrate to each other, the first substrate and the second substrate may be attached to each other so that the second spacer extends to the first substrate, and the second spacer is spaced apart from the first spacer in a direction parallel to the first substrate.

An electronic device according to an embodiment may include a processor outputting an image data signal and an input control signal and a display device driving based on the image data signal and the input control signal. The display device may include a first substrate, a display element layer disposed on the first substrate, and including a plurality of pixels, a second substrate disposed on the display element layer, and facing the first substrate, a first spacer disposed between the display element layer and the second substrate, and extending to the display element layer, and a second spacer disposed between the display element layer, and extending to the second substrate.

In a display device according to embodiments of the disclosure, a display device may include a display element layer disposed on a first substrate, a second substrate disposed on the display element layer and facing the first substrate, a first spacer disposed between the display element layer and the second substrate and contacting the display element layer, and a second spacer disposed between the display element layer and the second substrate and contacting the second substrate. A height of the second spacer may be greater than a height of the first spacer. Accordingly, a lifespan and a resolution of the display element layer may be improved. Accordingly, a luminous efficiency of the display device may be improved.

In a method of manufacturing the display device according to embodiments of the disclosure, after forming the first spacer on the display element layer and forming the second spacer on the second substrate, the first substrate and the second substrate may be attached to each other. Accordingly, a pressing phenomenon generated, in case that the second substrate is pressed against the display element layer while the first substrate and the second substrate are attached to each other, may be prevented. Accordingly, durability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment of the disclosure.

FIG. 2 is a schematic cross-sectional view illustrating a cross-section taken along line I-I′ of FIG. 1.

FIG. 3 is an enlarged schematic cross-sectional view illustrating area A of FIG. 2.

FIGS. 4, 5, 6, 7, 8, 9, and 10 are views schematic illustrating a method of manufacturing the display device of FIG. 2.

FIG. 11 is a schematic plan view illustrating a display device according to another embodiment of the disclosure.

FIG. 12 is a schematic cross-sectional view illustrating a cross-section taken along line II-II′ of FIG. 11.

FIGS. 13, 14, 15, and 16 are schematic views illustrating a method of manufacturing the display device of FIG. 11.

FIG. 17 is a schematic plan view illustrating a display device according to still another embodiment of the disclosure.

FIG. 18 is a schematic plan view illustrating a display device according to still another embodiment of the disclosure.

FIG. 19 is a schematic plan view illustrating a display device according to still another embodiment of the disclosure.

FIG. 20 is a block diagram of an electronic device according to an embodiment of the present disclosure.

FIG. 21 is a schematic diagram of the electronic device according to various embodiments of the present disclosure.

### DETAILED DESCRIPTION OF THE EMBODIMENTS

Hereinafter, display devices in accordance with embodiments will be described in more detail with reference to the accompanying drawings. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

The same reference numerals are used for the same components in the drawings, and redundant descriptions of the same components will be omitted.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

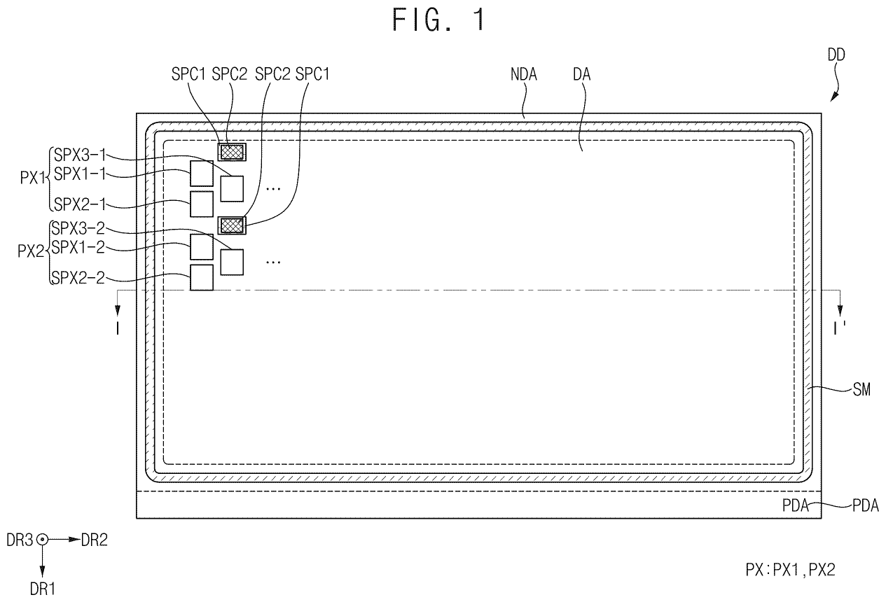

FIG. 1 is a schematic plan view illustrating a display device according to an embodiment of the disclosure.

Referring to FIG. 1, a display device DD according to an embodiment of the disclosure may include a display area DA, a non-display area NDA, and a pad area PDA. The display area DA may be defined as an area which generates an image, and the non-display area NDA may be defined as an area which does not generate an image.

In this specification, a plane may be defined by a first direction DR1 and a second direction DR2. For example, the first direction DR1 may be perpendicular to the second direction DR2. In addition, a third direction DR3 may be perpendicular to the plane.

At least one pixel PX may be disposed in the display area DA. Multiple pixels PX may be disposed in the direction DR1 and the second direction DR2. For example, the plurality of pixels PX may have a matrix. For example, the pixels PX may include a first pixel PX1 and a second pixel PX2. The first pixel PX1 and the second pixel PX2 may be spaced apart from each other. For example, the first pixel PX1 and the second pixel PX2 may be spaced apart in the first direction DR1.

Each of the first pixel PX1 and the second pixel PX2 may include multiple sub-pixels. For example, the first pixel PX1 may include a first-first sub-pixel SPX1-1, a second-first sub-pixel SPX2-1, and a third-first sub-pixel SPX3-1. The second pixel PX2 may include a first-second sub-pixel SPX1-2, a second-second sub-pixel SPX2-2, and a third-second sub-pixel SPX3-2. Each of the first-first sub-pixel SPX1-1, the second-first sub-pixel SPX2-1, and the third-first sub-pixel SPX3-1 may have substantially the same or similar size in a plan view. However, sizes of the sub-pixels according to embodiments of the disclosure are not limited thereto. For example, at least two sub-pixels among the first-first sub-pixel SPX1-1, the second-first sub-pixel SPX2-1, and the third-first sub-pixel SPX3-1 may have different sizes in a plan view.

The first-first sub-pixel SPX1-1 may emit first light, the second-first sub-pixel SPX2-1 may emit second light, and the third-first pixel SPX3-1 may emit third light. In an embodiment, the first light may be red light, the second light may be green light, and the third light may be blue light. However, the disclosure is not limited thereto. For example, the pixels PX may be combined to emit yellow, cyan, and magenta lights. The first-second sub-pixel SPX1-2, the second-second sub-pixel SPX2-2, and the third-second sub-pixel SPX3-2 may be substantially the same as or similar to the first-first sub-pixel SPX1-1, the second-first sub-pixel SPX2-1, and the third-first sub-pixel SPX3-1, respectively.

A first spacer SPC1 and a second spacer SPC2 may be disposed between two adjacent pixels among the pixels PX. For example, the first spacer SPC1 and the second spacer SPC2 may be disposed between the first pixel PX1 and the second pixel PX2. In addition, the first spacer SPC1 and the second spacer SPC2 may be disposed adjacent to an edge of the display area DA. Multiple first spacers SPC1 and the second spacers SPC2 may be arranged in the first direction DR1 and the second direction DR2. For example, as the pixels PX are arranged in a matrix, the first spacers SPC1 and the second spacers SPC2 may also have a matrix corresponding to an arrangement of the pixels PX.

The first spacers SPC1 and the second spacers SPC2 may be disposed in the display area DA. However, embodiments according to the disclosure are not limited thereto, and a first spacer SPC1 and a second spacer SPC2 may be disposed in the non-display area NDA.

The first spacers SPC1 and the second spacers SPC2 may overlap each other in a plan view. In an embodiment, in a plan view, an area of a first spacer SPC1 may be larger than an area of a second spacer SPC2. However, embodiments of the disclosure are not limited thereto, and in a plan view, an area of a first spacer SPC1 may be smaller than or substantially equal to an area of a second spacer SPC2.

In an embodiment, a first spacer SPC1 may have a rectangular shape in a plan view. However, the disclosure is not limited thereto, and a first spacer SPC1 may have various shapes such as a polygon or a circle in a plan view.

In an embodiment, a second spacer SPC2 may have a rectangular shape in a plan view. However, the disclosure is not limited thereto, and a second spacer SPC2 may have various shapes such as a polygon or a circle in a plan view.

In an embodiment, a planar shape of a second spacer SPC2 may be substantially the same as or similar to the planar shape of a first spacer SPC1. In other embodiments, a planar shape of a second spacer SPC2 may be different from a planar shape of a first spacer SPC1.

The non-display area NDA may be located around the display area DA. For example, the non-display area NDA may surround at least a part of the display area DA. A gate driver, a light-emitting controller, and the like, which provide a gate signal or voltage to the pixel PX may be disposed in the non-display area NDA.

A scaling member SM may be disposed in the non-display area NDA. In other words, the sealing member SM may not be disposed in the display area DA and the pad area PDA. The sealing member SM may surround at least a portion of the display area DA. For example, the sealing member SM may surround an entire periphery of the display area DA. In an embodiment, the scaling member SM may surround at least a portion of each of the first spacers SPC1 and the second spacers SPC2.

The pad area PDA may be adjacent to a side of the non-display area NDA. For example, the pad area PDA may be adjacent to the non-display area NDA in the first direction DR1. In addition, the pad area PDA may be spaced apart from the display area DA. For example, the pad area PDA may be spaced apart from a side of the display area DA in the first direction DR1. A data driver, a power voltage supplier, and the like that provide data signals or voltages to pixels PX may be disposed in the pad area PDA.

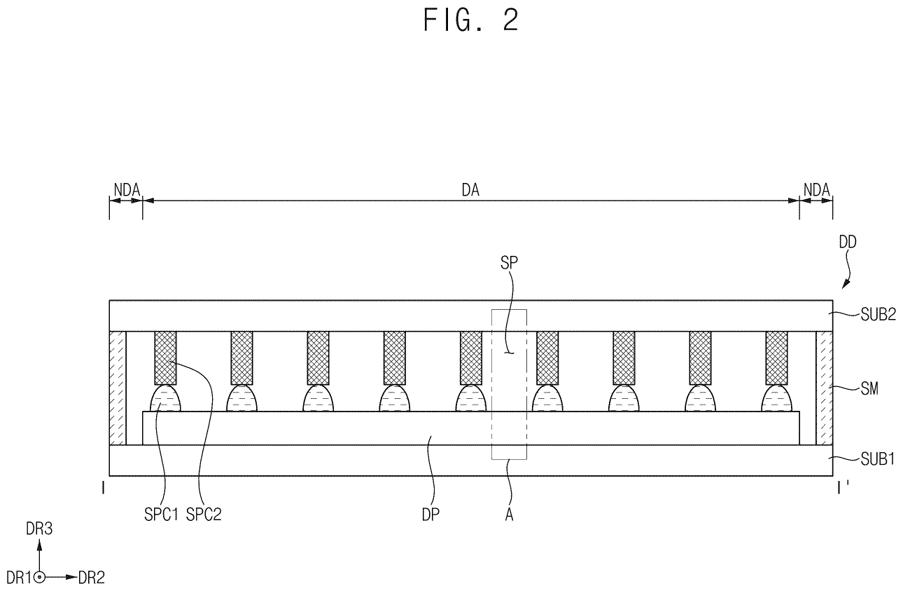

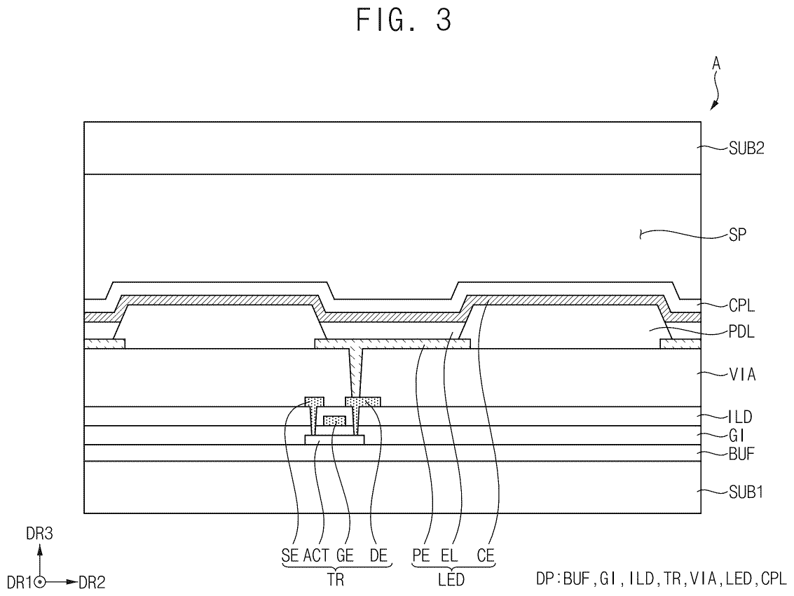

FIG. 2 is a schematic cross-sectional view illustrating a cross-section taken along line I-I′ of FIG. 1. FIG. 3 is an enlarged schematic cross-sectional view illustrating area A of FIG. 2.

Referring to FIGS. 2 and 3, the display device DD may include a first substrate SUB1, a display element layer DP, the first spacers SPC1, the second spacers SPC2, the sealing member SM (or members), a second substrate SUB2, and a protective layer PL. The display element layer DP may include a buffer layer BUF, a gate insulating layer GI, an interlayer insulating layer ILD, a transistor TR, a via insulating layer VIA, a pixel defining layer PDL, a light-emitting element LED, and a capping layer CPL. The transistor TR may include an active pattern ACT, a gate electrode GE, a source electrode SE, and a drain electrode DE. The light-emitting element LED may include a pixel electrode PE, an light-emitting layer EL, and a common electrode CE.

The first substrate SUB1 may include a transparent material or an opaque material. The first substrate SUB1 may be a base substrate that provides a base of the display device DD. For example, the first substrate SUB1 may include a rigid glass substrate, a polymer substrate, a flexible film, a metal substrate, and the like. These may be used alone or in combination with each other. In an embodiment, the first substrate SUB1 may include a rigid glass substrate.

The display element layer DP may be disposed on the first substrate SUB1. For example, the display element layer DP may be disposed over the display area DA of the first substrate SUB1. However, the disclosure is not limited thereto, and a portion of the display element layer DP may also be disposed in the non-display area NDA. The display element layer DP may include a pixel PX of FIG. 1. Accordingly, light may be emitted from the display element layer DP.

The buffer layer BUF may be disposed on the first substrate SUB1. The buffer layer BUF may prevent metal atoms or impurities from diffusing from the first substrate SUB1 to the transistor TR. In addition, the buffer layer BUF may improve a flatness of a surface of the first substrate SUB 1 in case that the surface of the first substrate SUB1 is not uniform. The buffer layer BUF may include an inorganic material such as a silicon oxide (SiOx), a silicon nitride (SiNx), a silicon oxynitride (SiOxNy), and the like. These may be used alone or in combination with each other.

The active pattern ACT may be disposed on the buffer layer BUF. The active pattern ACT may include a source area, a drain area, and a channel area located between the source area and the drain area. The active pattern ACT may include a silicon semiconductor material or an oxide semiconductor material. Examples of the silicon semiconductor material may include an amorphous silicon, a polycrystalline silicon, and the like. Examples of the above oxide semiconductor material may include an indium gallium zinc oxide (IGZO), an indium tin zinc oxide (ITZO), and the like. These may be used alone or in combination with each other.

The gate insulating layer GI may be disposed on the buffer layer BUF. The gate insulating layer GI may sufficiently cover the active pattern ACT and may have a substantially flat upper surface without generating a step around the active pattern ACT. In other embodiments, the gate insulating layer GI may cover the active pattern ACT and may be disposed along the profile of the active pattern ACT with a uniform thickness. The gate insulating layer GI may include an inorganic material such as silicon oxide (SiOx), silicon nitride (SiNx), silicon carbide (SiCx), silicon oxynitride (SiOxNy), silicon oxycarbide (SiOxCy), and the like. These may be used alone or in combination with each other.

The gate electrode GE may be disposed on the gate insulating layer GI. The gate electrode GE may overlap the channel area of the active pattern ACT. The gate electrode GE may include a metal, an alloy metal nitride, a conductive metal oxide, a metal nitride, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. Examples of the metal nitride may include aluminum nitride (AlNx), tungsten nitride (WNx), chromium nitride (CrNx), and the like. These may be used alone or in combination with each other.

The interlayer insulating layer ILD may be disposed on the gate insulating layer GI. The interlayer insulating layer ILD may sufficiently cover the gate electrode GE and may have a substantially flat upper surface without forming a step around the gate electrode GE. In other embodiments, the interlayer insulating layer ILD may cover the gate electrode GE and may be disposed along the profile of the gate electrode GE with a uniform thickness. The interlayer insulating layer ILD may include an inorganic material such as a silicon oxide, a silicon nitride, a silicon carbide, a silicon oxynitride, a silicon oxycarbide, and the like. These may be used alone or in combination with each other.

A source electrode SE and a drain electrode DE may be disposed on the interlayer insulating layer ILD. The source electrode SE may be connected to the source area of the active pattern ACT through a first contact hole penetrating the gate insulating layer GI and a first portion of the interlayer insulating layer ILD. In addition, the drain electrode DE may be connected to the drain area of the active pattern ACT through a second contact hole penetrating the second portion of the gate insulating layer GI and the interlayer insulating layer ILD. For example, each of the source electrode SE and the drain electrode DE may include a metal, an alloy, a metal nitride, a conductive metal oxide, a transparent conductive material, and the like. These may be used alone or in combination with each other.

Accordingly, a transistor TR including the active pattern ACT, the gate electrode GE, the source electrode SE, and the drain electrode DE may be disposed on the first substrate SUB1.

The pixel electrode PE may be disposed on the via insulating layer VIA. The pixel electrode PE may be connected to the drain electrode DE through a contact hole penetrating the via insulating layer VIA. The pixel electrode PE may include a metal, an alloy, a metal nitride, a conductive metal oxide, a transparent conductive material, and the like. These may be used alone or in combination with each other. For example, the pixel electrode PE may perform as an anode.

The pixel defining layer PDL may be disposed on the via insulating layer VIA. The pixel defining layer PDL may cover at least a portion of the pixel electrode PE. For example, the pixel defining layer PDL may cover an edge of the pixel electrode PE. For example, an opening exposing at least a portion of an upper surface of the pixel electrode PE may be defined in the pixel defining layer PDL. The pixel defining layer PDL may include an inorganic material and/or an organic material. For example, the pixel defining layer PDL may include an organic material such as an epoxy resin, a siloxane resin, and the like. These may be used alone or in combination with each other. As another example, the pixel defining layer PDL may include an inorganic material and/or an organic material containing a light-blocking material having a black color.

The first spacers SPC1 may be disposed on the display element layer DP. In an embodiment, the first spacers SPC1 may be disposed on the capping layer CPL. In other embodiments, the first spacers SPC1 may be disposed on the pixel defining layer PDL. In this case, the common electrode CE and the capping layer CPL may cover the first spacers SPC1.

The first spacers SPC1 may protrude from the display element layer DP in the third direction DR3. The first spacer SPC1 may have a dome shape. However, the disclosure is not limited thereto, and the first spacer SPC1 may have various shapes such as a cylinder, a triangular column, a square column, a pentagonal column, a hexagonal column, and the like.

The first spacers SPC1 may be formed simultaneously with the pixel defining layer PDL through a same process. In this case, the first spacers SPC1 may include a same material as the pixel defining layer PDL. As another example, the first spacers SPC1 may be formed through a separate process from the pixel defining film PDL. In this case, the first spacers SPC1 may include a different material from the pixel defining film PDL or may include a same material.

The first spacers SPC1 may be spaced apart from the second substrate SUB2. Specifically, the first spacers SPC1 may be spaced apart from the second substrate SUB2 in the third direction DR3. In other words, the first spacers SPC1 may not contact (extend to) the second substrate SUB2.

The second spacers SPC2 may be disposed on the first spacer SPC1. For example, the second spacers SPC2 may contact (extend to) the first spacers SPC1. The second spacers SPC2 may be disposed between the display element layer DP and the second substrate SUB2. For example, the second spacers SPC2 may be disposed between the first spacers SPC1 and the second substrate SUB2. Specifically, an upper surface of the second spacers SPC2 may contact the second substrate SUB2. In addition, a rear surface of the second spacers SPC2 may contact an upper surface of the first spacers SPC1.

In an embodiment, a second spacer SPC2 may have a shape of a square pillar. However, the disclosure is not limited thereto, and a second spacer SPC2 may have various shapes such as a cylinder, a triangular pillar, a pentagonal pillar, a hexagonal pillar, and the like.

In an embodiment, the second spacers SPC2 may include an organic material. For example, the organic material may include polyimide (PI), polystyrene (PS), and the like. These may be used alone or in combination.

In an embodiment, the second spacers SPC2 may include an organic material and an inorganic material. For example, the inorganic material may include silicon oxide (SiOx), silicon nitride (SiNx), silicon oxynitride (SiOxNy), and the like. In this case, the second spacers SPC2 may include a first layer including the organic material and a second layer including the inorganic material. The first layer may contact the first spacers SPC1. In addition, the second layer may be disposed on the first layer and may contact the second substrate SUB2. However, the disclosure is not limited thereto, and the second spacers SPC2 may have a single-layer structure or a multi-layer structure including three or more layers.

In an embodiment, the second spacers SPC2 may include an organic material, an inorganic material, and a light-blocking material. For example, the light-blocking material may be a black dye, a black pigment, and the like, and may include a metal (e.g., carbon black, chromium, and the like) and a metal oxide. Accordingly, the second spacers SPC2 may absorb or block external light incident through the second substrate SUB2. In addition, the second spacers SPC2 may absorb or block reflected light reflected by the pixel defining layer PDL from the external light.

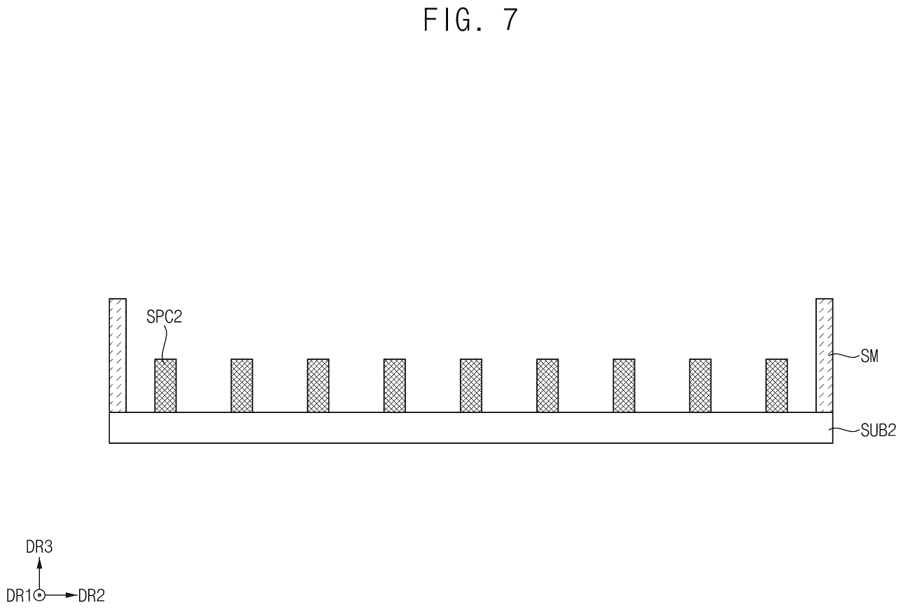

The second spacers SPC2 may be formed through a separate process from the first spacers SPC1. This will be described later with reference to FIG. 7.

The first and second spacers SPC1, SPC2 may prevent the display characteristics of the display device DD from being deteriorated by external impact. The first and second spacers SPC1, SPC2 may serve to maintain a space SP between the first substrate SUB1 and the second substrate SUB2. In addition, The first and second spacers SPC1, SPC2 may perform to support a fine metal mask (FMM) used to deposit an organic light-emitting material.

The light-emitting layer EL may be disposed on the pixel electrode PE. Specifically, the light-emitting layer EL may be disposed in the opening of the pixel defining layer PDL. The light-emitting layer EL may include an organic light-emitting material that emits light of a preset color. For example, the light-emitting layer EL may include an organic light-emitting material that emits red light, green light, or blue light.

The common electrode CE may be disposed on the light-emitting layer EL, the pixel defining layer PDL, and the first and second spacers SPC1, SPC2. The common electrode CE may be a plate electrode. The common electrode CE may include a metal, an alloy, a metal nitride, a conductive metal oxide, a transparent conductive material, and the like. These may be used alone or in combination with each other. For example, the common electrode CE may perform as a cathode.

Accordingly, a light-emitting element LED including a pixel electrode PE, an emission layer EL, and a common electrode CE may be disposed on a first substrate SUB1. The light-emitting element LED may be electrically connected to the transistor TR.

A capping layer CPL may be disposed on the common electrode CE. The capping layer CPL may protect the common electrode CE. The capping layer CPL may include an organic insulating material and/or an inorganic insulating material.

A sealing member SM may be disposed on the first substrate SUB1. For example, the scaling member SM may be disposed in a non-display area NDA on the first substrate SUB1. The sealing member SM may be disposed between the first substrate SUB1 and the second substrate SUB2. For example, the sealing member SM may be disposed between the first substrate SUB1 and the second substrate SUB2 along the edges of each of the first substrate SUB1 and the second substrate SUB2. In addition, the scaling member SM may surround at least a portion of each of the display element layer DP, the first spacers SPC1, and the second spacers SPC2.

In an embodiment, a height of the sealing member SM may be greater than a height of the first spacers SPC1. In an embodiment, a height of the sealing member SM may be greater than a height of the second spacers SPC2. In addition, in an embodiment, a height of the sealing member SM may be greater than a sum of a height of the first spacers SPC1 and a height of the second spacers SPC2.

The first substrate SUB1 and the second substrate SUB2 may be attached by a sealing member SM. Since the space SP between the first substrate SUB1 and the second substrate SUB2 is sealed by the scaling member SM, external moisture, air, impurities, and the like may be prevented from penetrating into the space SP. For example, the sealing member SM may include an organic material such as an epoxy resin.

The second substrate SUB2 may be disposed on the first substrate SUB1. For example, the second substrate SUB2 may be disposed on the sealing member SM and the second spacers SPC2. Specifically, the second substrate SUB2 may contact the sealing member SM and the second spacers SPC2. The second substrate SUB2 may face the first substrate SUB1. The second substrate SUB2 may be spaced apart from the first substrate SUB1 in a third direction DR3 intersecting the first direction DR1 and the second direction DR2, respectively. For example, the third direction DR3 may be perpendicular to the first direction DR1 and the second direction DR2, respectively. Accordingly, the space SP between the first substrate SUB1 and the second substrate SUB2 may be defined. In an embodiment, the space SP may be in a vacuum state. In another embodiment, the space SP may be filled with a filler.

The second substrate SUB2 may include a transparent material or an opaque material. The second substrate SUB2 may be an encapsulation substrate that protects the display element layer DP. For example, the second substrate SUB2 may include a rigid glass substrate, a polymer substrate, a flexible film, a metal substrate, and the like. These may be used alone or in combination with each other. In an embodiment, the second substrate SUB2 may include a glass substrate having rigidity.

As described above, the display device DD may include the display element layer DP disposed on the first substrate SUB1, the second substrate SUB2 disposed on the display element layer DP and facing the first substrate SUB1, the first spacers SPC1 disposed between the display element layer DP and the second substrate SUB2 and contacting the display element layer DP, and the second spacers SPC2 disposed between the display element layer DP and the second substrate SUB2 and contacting the second substrate SUB2. The height of the second spacers SPC2 may be greater than the height of the first spacers SPC1. Accordingly, the lifespan and resolution of the display element layer DP may be improved. Accordingly, the luminous efficiency of the display device DD may be improved.

Specifically, during a process of forming the first spacers SPC1 through a deposition mask, if the height of the first spacers SPC1 are formed large so that the first spacers SPC1 and the second substrate SUB2 contact with each other, a shadow effect may be generated in which a deposition material is not deposited at a specific location.

In case that the second spacers SPC2 are formed on the second substrate SUB2, the first spacers SPC1 may not have to contact the second substrate SUB2, so a height of the first spacers SPC1 may be formed smaller than in case that the second spacers SPC2 are not formed on the second substrate SUB2, and an area of the light-emitting layer EL may be formed relatively larger in the display element layer DP while preventing a generation of the shadow effect.

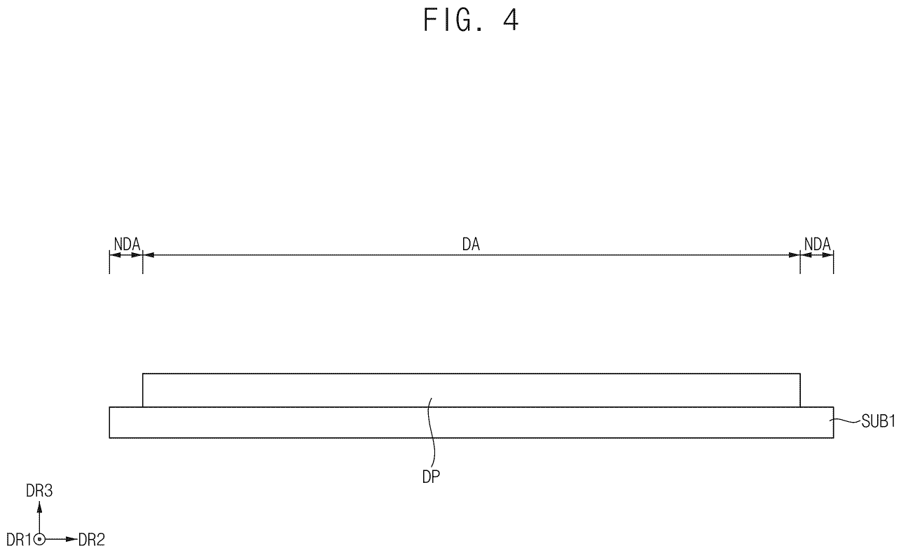

FIGS. 4, 5, 6, 7, 8, 9, and 10 are schematic views illustrating a method of manufacturing the display device of FIG. 2.

Referring to FIG. 4, the display element layer DP may be formed on a surface of a first substrate SUB1. For example, the display element layer DP may be formed in the display area DA on the first substrate SUB1. However, the disclosure is not limited thereto, and a portion of the display element layer DP may also be disposed in the non-display area NDA on the first substrate SUB1. The display element layer DP may have a multilayer structure as illustrated in FIG. 3.

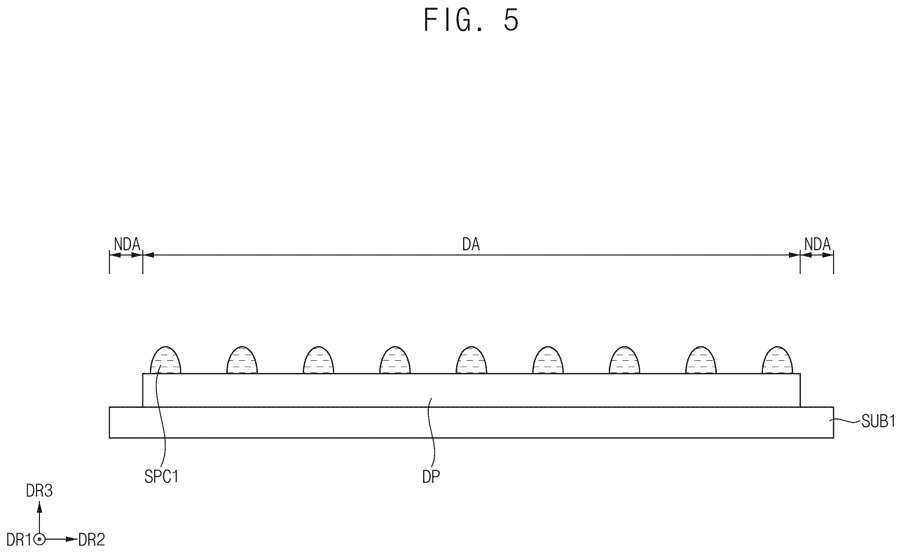

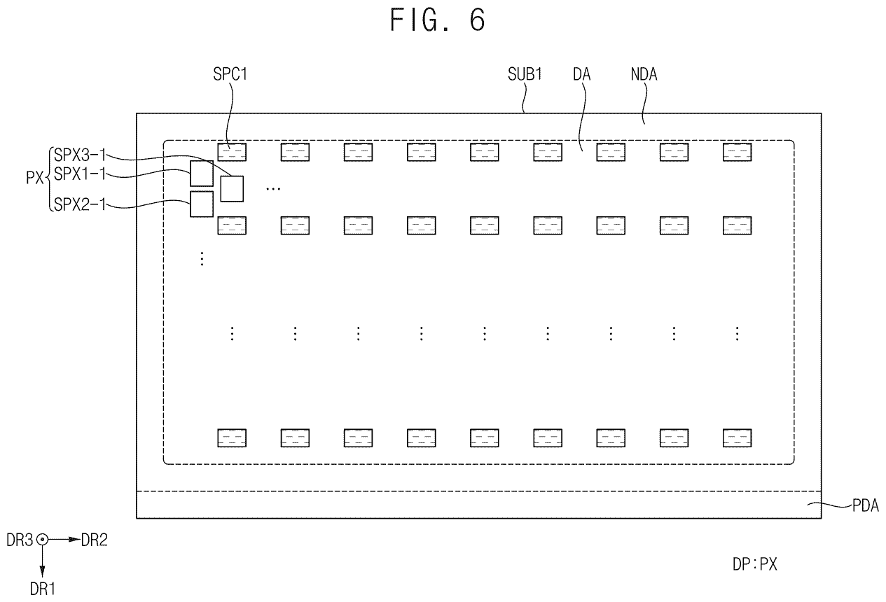

Referring to FIGS. 5 and 6, the first spacer SPC1 may be disposed on the display element layer DP. Multiple first spacers SPC1 may be disposed on the display element layer DP. Specifically, the pixels PX included in the display element layer DP may be arranged along the first direction DR1 and the second direction DR2 in the display area DA. A first spacer SPC1 may be disposed between two adjacent pixels among the pixels PX in a plane parallel to the display element layer DP. In other words, the first spacers SPC1 may be regularly arranged in the first direction DR1 and the second direction DR2 according to the arrangement of the pixels PX. Each of the first spacers SPC1 may be spaced apart from each other. For example, two adjacent first spacers SPC1 among the first spacers SPC1 may be spaced apart from each other in the first direction DR1 or the second direction DR2.

The first spacers SPC1 may be formed in the display area DA on the display element layer DP. However, the disclosure is not limited thereto, and a portion of the first spacers SPC1 located at an edge of the display area DA among the first spacers SPC1 may also be disposed in the non-display area NDA.

The first spacers SPC1 may be formed through a deposition mask. An opening corresponding to the position of a first spacer SPC1 may be defined in the deposition mask. For example, a material forming the first spacer SPC1 may be formed on the display element layer DL by penetrating the opening of the deposition mask. For example, the deposition mask may be a fine metal mask (FMM). However, a type of mask for forming the first spacer SPC1 in the disclosure is not limited thereto.

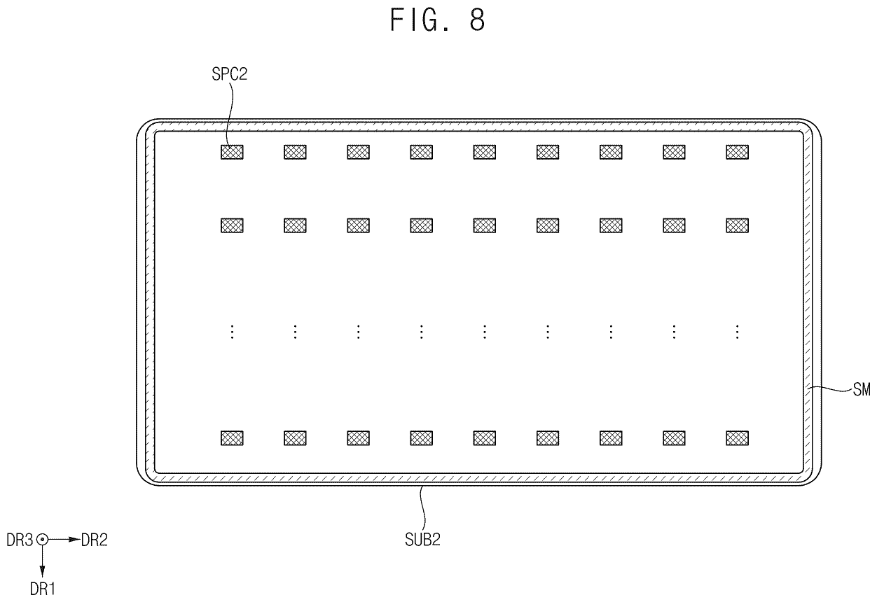

Referring to FIGS. 7 and 8, the sealing member SM may be formed on a surface of the second substrate SUB2. The surface may face a third direction DR3. However, the direction in which the surface of the second substrate SUB2 of the disclosure faces is not limited thereto. The sealing member SM may be formed on an edge of the second substrate SUB2. In addition, the second spacer SPC2 may be formed on the surface of the second substrate SUB2.

The second spacer SPC2 may be formed inside the sealing member SM on the second substrate SUB2. Specifically, the second spacer SPC2 may be formed on a portion of the second substrate SUB2 surrounded by the sealing member SM. The second spacers SPC2 may be arranged in the first direction DR1 and the second direction DR2 on the surface of the second substrate SUB2. Each of the second spacers SPC2 may be spaced apart from each other. For example, two adjacent second spacers SPC2 among the second spacers SPC2 may be spaced apart from each other in the first direction DR1 or the second direction DR2.

A location of each of the second spacers SPC2 on the second substrate SUB2 may correspond to a location of each of the first spacers SPC1 on the first substrate SUB1 of FIGS. 5 and 6.

In an embodiment, the second spacers SPC2 may be formed after the sealing member SM is formed on the surface of the second substrate SUB2. In another embodiment, the scaling member SM and the second spacers SPC2 may be formed simultaneously on the surface of the second substrate SUB2. In still another embodiment, the sealing member SM may be formed after the second spacers SPC2 are formed on the surface of the second substrate SUB2.

In an embodiment, the second spacers SPC2 may be formed through an exposure process. For example, a material forming the second spacers SPC2 may be applied entirely on the surface of the second substrate SUB2, and the second spacers SPC2 may be formed using a photoresist and a photomask. The photoresist may be a positive photoresist. In other embodiments, the photoresist may be a negative photoresist.

However, the manufacturing process of the second spacers SPC2 according to the embodiments of the disclosure is not limited thereto, and the second spacers SPC2 may be formed through a laser exposure process, a 3D printer process, and the like.

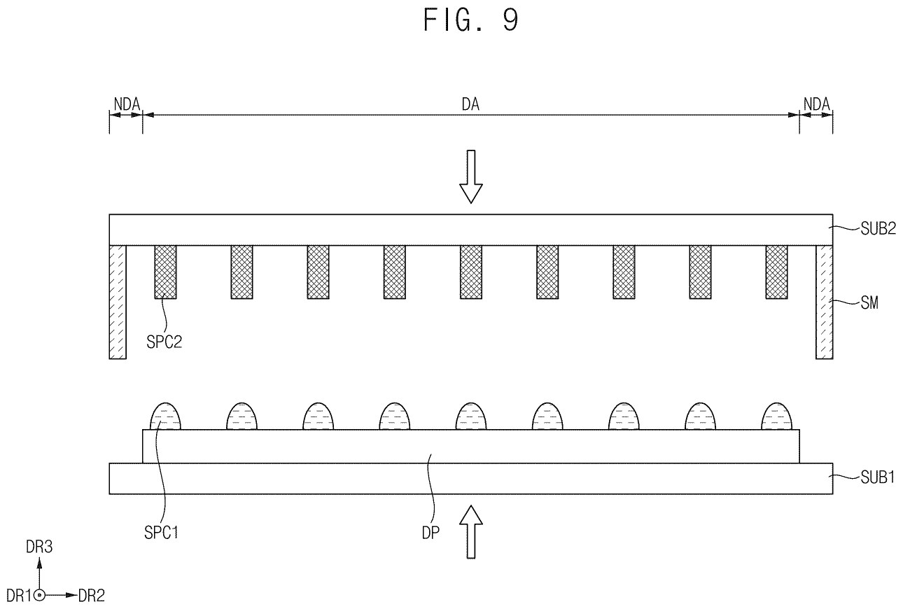

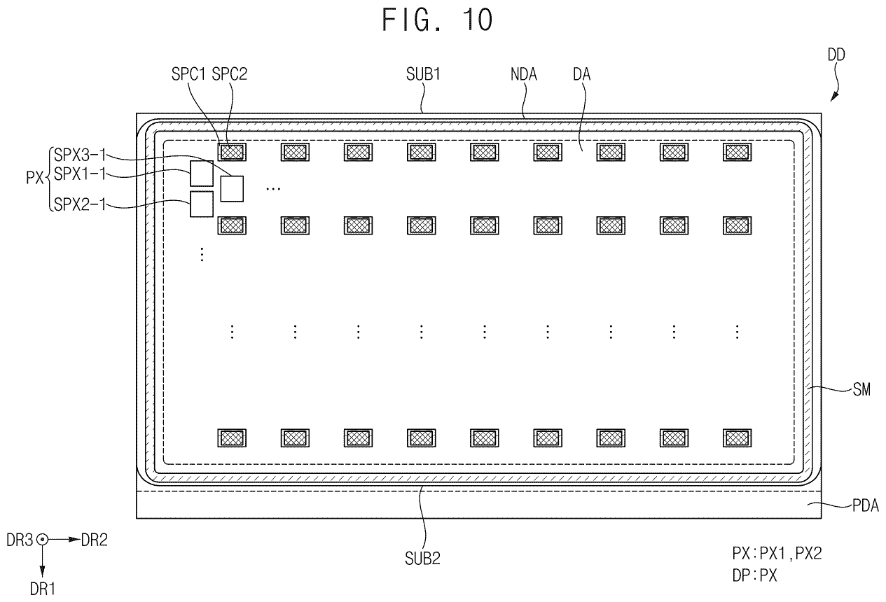

Referring to FIGS. 9 and 10, the first substrate SUB1 and the second substrate SUB2 may be attached to each other. During a process of attaching the first substrate SUB1 and the second substrate SUB2, a surface of each of the sealing member SM on the second substrate SUB2 and the second spacers SPC2 may face the first substrate SUB1. In other words, the second substrate SUB2 may be flipped over so that the surface of the second substrate SUB2 of FIGS. 7 and 8 faces a direction opposite to the third direction DR3.

The second substrate SUB2 may be attached to the first substrate SUB1 so that the second substrate SUB2 overlaps a portion of the display area DA and the non-display area NDA of the first substrate SUB1. In other words, the second substrate SUB2 may not overlap the pad area PDA of the first substrate SUB1. However, the disclosure is not limited thereto, and the second substrate SUB2 may overlap at least a portion of the pad area PDA of the first substrate SUB1.

A height of the sealing member SM formed on the second substrate SUB2 may be greater than a height of the second spacers SPC2 formed on the second substrate SUB2. Accordingly, in case that the first substrate SUB 1 and the second substrate SUB2 are attached, the first substrate SUB1 and the second substrate SUB2 may be attached to each other through the sealing member SM.

The first spacers SPC1 and the second spacers SPC2 may face each other. Accordingly, in case that the first substrate SUB1 and the second substrate SUB2 are attached, a surface of the second spacers SPC2 facing the first spacers SPC1 and a surface of the first spacers SPC1 facing the second spacers SPC2 may contact each other. Specifically, in case that the first substrate SUB1 and the second substrate SUB2 are attached, each of the first spacers SPC1 may contact each of the opposing second spacers SPC2.

The first spacers SPC1 and the second spacers SPC2 may contact each other to fill a portion of the space between the display element layer DP and the second substrate SUB2.

As described above, since a first spacer SPC1 is disposed between two adjacent pixels PX among the pixels PX, the second spacers SPC2 may also be disposed between two adjacent pixels PX among the pixels PX.

A roller may be used while the first substrate SUB1 and the second substrate SUB2 are attached to each other. For example, a process of applying pressure to the second substrate SUB2 using a roller, so that the second substrate SUB2 is completely pressed against the display element layer DP, may be performed. After the first substrate SUB1 and the second substrate SUB2 are attached to each other, the display device DD of FIG. 1 may be manufactured.

As described above, a height of the first spacers SPC1 in a case where the second spacers SPC2 are not formed on the second substrate SUB2 may be relatively smaller than a height of the first spacers SPC1 in the case where the second spacers SPC2 are formed on the second substrate SUB2, in order to prevent the shadow phenomenon. Accordingly, a distance between the second substrate SUB2 and the display element layer DP may be relatively smaller in the case where the second spacers SPC2 are not formed on the second substrate SUB2 than in the case where the second spacers SPC2 are formed on the second substrate SUB2. Accordingly, if the second spacers SPC2 are not formed on the second substrate SUB2, a pressing phenomenon may be generated in case that the second substrate SUB2 is pressed against the display element layer DP while the first substrate SUB1 and the second substrate SUB2 are attached to each other.

In contrast, in the method for manufacturing the display device DD described with reference to FIGS. 4, 5, 6, 7, 8, 9, and 10, the first spacers SPC1 may be formed on the display element layer DP, and the second spacers SPC2 may be formed on the second substrate SUB2, and the first substrate SUB1 and the second substrate SUB2 may be attached to each other. Accordingly, the pressing phenomenon generated in case that the second substrate SUB2 is pressed against the display element layer DP while the first substrate SUB1 and the second substrate SUB2 are attached to each other may be prevented. Accordingly, a durability of the display device may be improved.

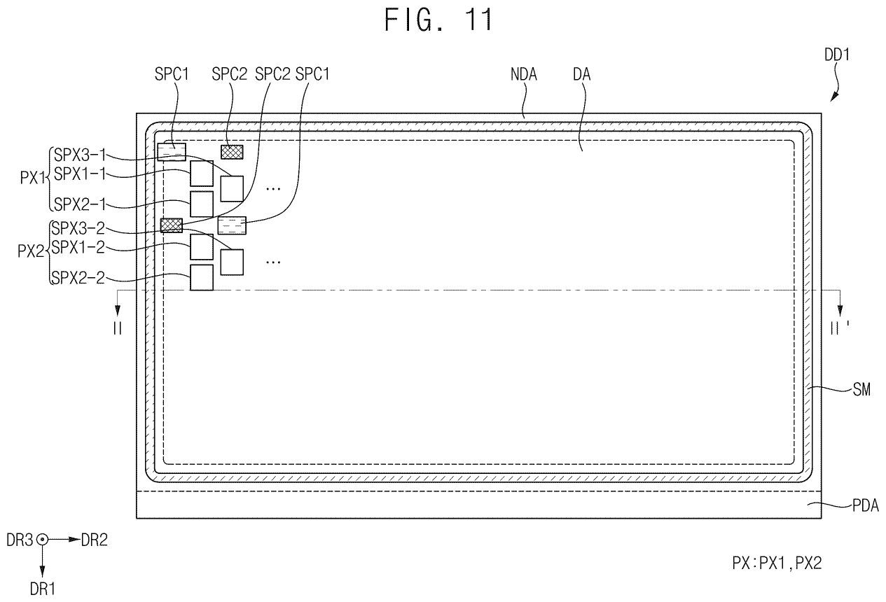

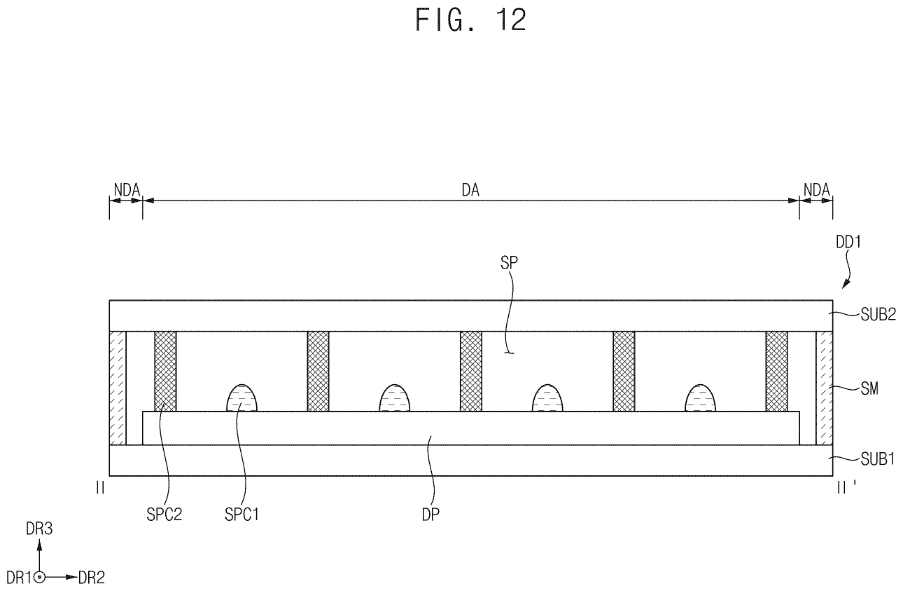

FIG. 11 is a schematic plan view illustrating a display device according to another embodiment of the disclosure. FIG. 12 is a cross-sectional view illustrating a cross-section taken along line II-II′ of FIG. 11.

A display device DD1 described with reference to FIGS. 11 and 12 may be substantially the same as or similar to the display device DD described with reference to FIGS. 1 and 2 except for an arrangement of the first spacer SPC1 and the second spacer SPC2.

Hereinafter, contents overlapping with contents described with reference to FIGS. 1 and 2 will be omitted or simplified.

Referring to FIGS. 11 and 12, the second spacers SPC2 may be spaced apart from the first spacers SPC1. For example, a second spacer SPC2 may be spaced apart from a first spacer SPC1 in a direction parallel to the first substrate SUB1. Specifically, each of the second spacers SPC2 may be spaced apart from the first spacers SPC1 in the first direction DR1 and the second direction DR2. In other words, the second spacers SPC2 may not overlap the first spacers SPC1 in a plan view.

The second spacers SPC2 may be arranged between the display element layer DP and the second substrate SUB2. For example, the second spacers SPC2 may contact each of the display element layer DP and the second substrate SUB2.

On the first substrate SUB 1, the first spacers SPC1 and the second spacers SPC2 may be arranged alternately along the second direction DR2 based on a row parallel to the second direction DR2. On the first substrate SUB1, the first spacers SPC1 and the second spacers SPC2 may be arranged alternately along the first direction DR1 based on a column parallel to the first direction DR1. However, an arrangement of the first spacers SPC1 and the second spacers SPC2 according to the embodiments of the disclosure is not limited thereto, and the first spacers SPC1 and the second spacers SPC2 may have various arrangements so that they do not overlap each other in a plan view.

A first spacer SPC1 may be disposed between two adjacent pixels among the pixels PX. If the first spacer SPC1 is not disposed between two adjacent pixels among the pixels PX, a second spacer SPC2 may be selectively disposed between two adjacent pixels among the pixels PX.

In an embodiment, a height of the second spacers SPC2 may be greater than a height of the first spacers SPC1. Specifically, a surface of the second spacers SPC2 may contact the second substrate SUB2, and another surface opposite to the surface may contact the display element layer DP. A surface of the first spacers SPC1 may contact the display element layer DP, but another surface of the first spacers SPC1 opposite to the surface may be spaced apart from the second substrate SUB2.

In an embodiment, a height of the second spacers SPC2 may be smaller than a height of the sealing member SM. In addition, a height of the first spacers SPC1 may be smaller than a height of the sealing member SM.

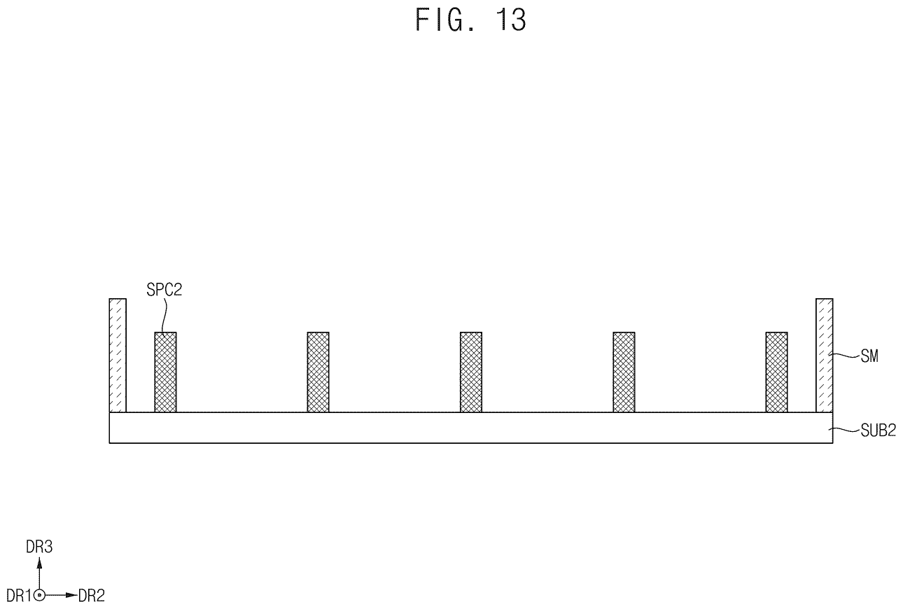

FIGS. 13, 14, 15, and 16 are schematic views illustrating a method of manufacturing the display device of FIG. 11.

The method for manufacturing the display device DD1 described with reference to FIGS. 13 to 16 may be substantially the same as or similar to the method for manufacturing the display device DD described with reference to FIGS. 4 to 10, except for the positions where the first spacers SPC1 and the second spacers SPC2 are formed.

Hereinafter, any content overlapping with the content described with reference to FIGS. 3 to 10 will be omitted or simplified.

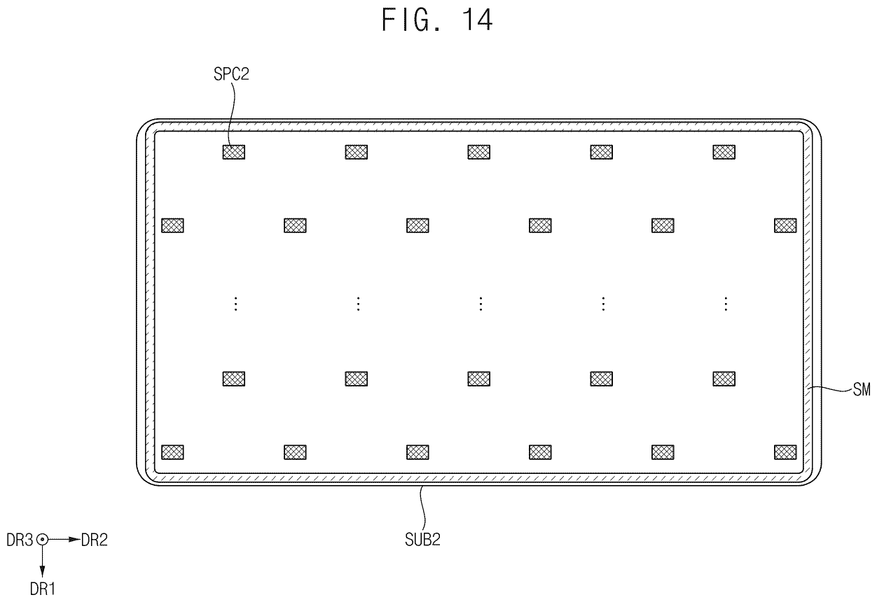

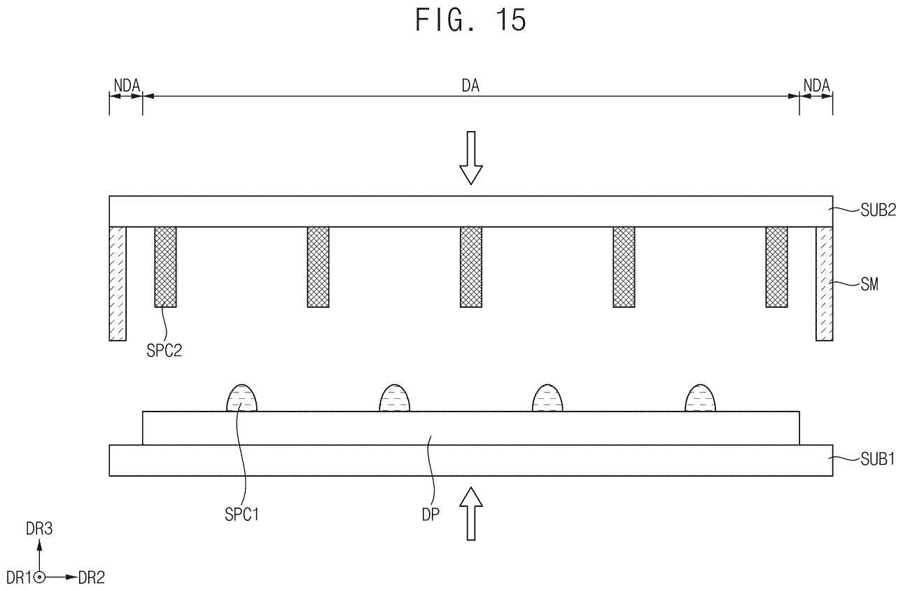

Referring to FIGS. 13 and 14, the sealing member SM and the second spacers SPC2 may be formed on a surface of the second substrate SUB2. A location of the second spacers SPC2 in a plan view may not correspond to a location of the first spacers SPC1 of FIG. 15. In other words, the second spacers SPC2 may be arranged so that the second spacers SPC2 may not overlap the first spacers SPC1 in a plan view.

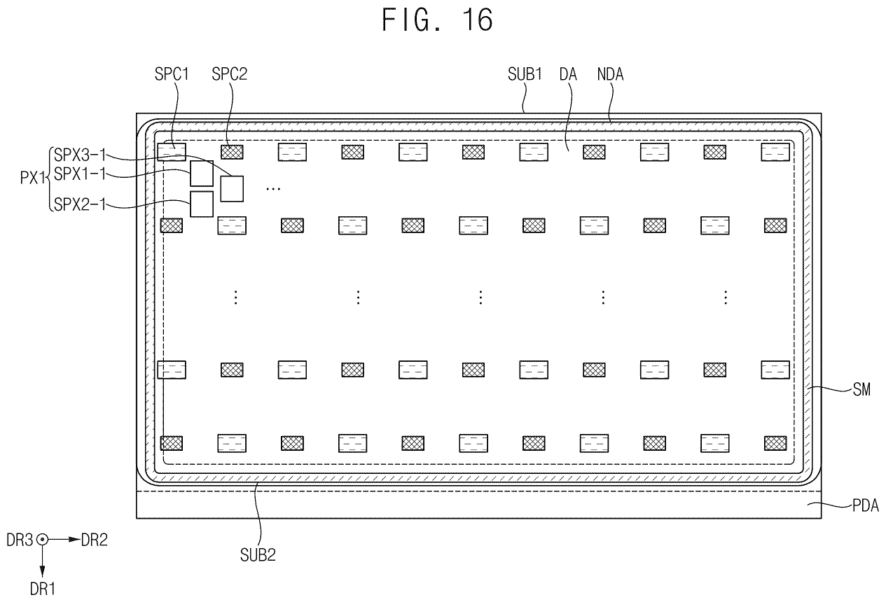

Referring to FIGS. 15 and 16, the first spacers SPC1 and the second spacers SPC2 may not face each other. Accordingly, in case that the first substrate SUB1 and the second substrate SUB2 are attached, the second spacers SPC2 may be spaced apart from the first spacers SPC1. Specifically, a surface of each of the second spacers SPC2 facing in a direction opposite to the third direction DR3 may contact the display element layer DP. In addition, a surface of each of the first spacers SPC1 facing in the third direction DR3 may face the second substrate SUB2.

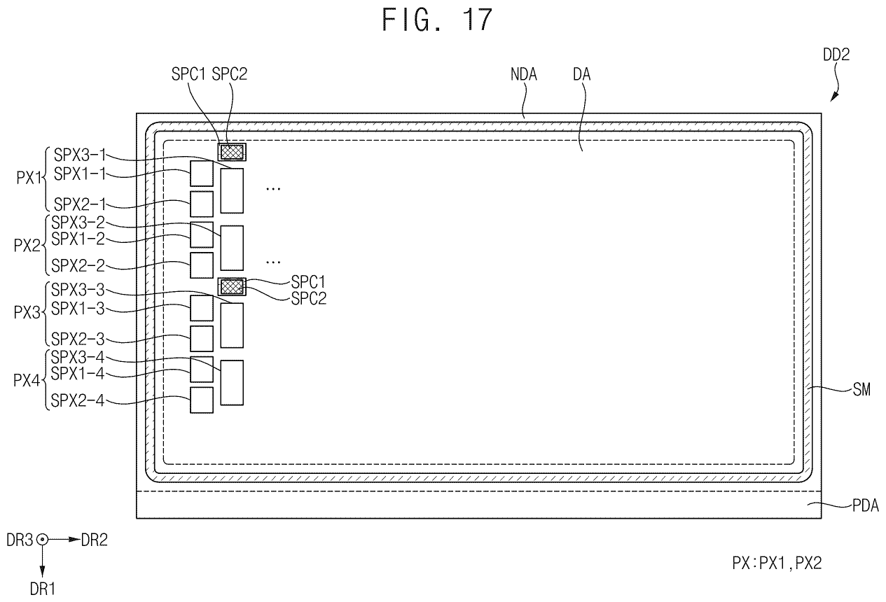

FIG. 17 is a schematic plan view illustrating a display device according to still another embodiment of the disclosure.

A display device DD2 described with reference to FIG. 17 may be substantially the same as or similar to the display device DD described with reference to FIG. 1 except for the arrangement of the pixels PX, the first spacers SPC1, and the second spacers SPC2.

Hereinafter, contents overlapping with contents described with reference to FIG. 1 will be omitted or simplified.

Referring to FIG. 17, a length of the third-first sub-pixel SPX3-1 in the first direction DR1 may be greater than a length of each of the first-first sub-pixel SPX1-1 and the second-first sub-pixel SPX2-1 in the first direction DR1. A length of the third-second sub-pixel SPX3-2 in the first direction DR1 may also be greater than a length of each of the first-first sub-pixel SPX1-2 and the second-second sub-pixel SPX2-2 in the first direction DR1. In other words, a length of the sub-pixel emitting the third light in the first direction DR1 may be greater than a length of each of the sub-pixels emitting the first light and the second light in the first direction DR1.

A first spacer SPC1 and a second spacer SPC2 may be arranged between two adjacent pixel sets, with the two pixels PX defining a single pixel set. For example, in case that the first pixel PX1 and the second pixel PX2 are defined as a first pixel set and the third pixel PX3 and the fourth pixel PX4 are defined as a second pixel set, a first spacer SPC1 and a second spacer SPC2 may be arranged between the first pixel set and the second pixel set. Specifically, the first spacer SPC1 and the second spacer SPC2 may be arranged between the third-second sub-pixel SPX3-2 included in the second pixel PX2 and the first-third sub-pixel SPX1-3 included in the third pixel PX3. In addition, each of the first spacer SPC1 and the second spacer SPC2 may be arranged in the first direction DR1 and the second direction DR2 one by one for each pixel set. However, according to embodiments of the disclosure, the pixel set is not limited thereto, and the pixel set may include three or more pixels PX.

Among the first spacers SPC1, the first spacers SPC1 adjacent to the sealing member SM may be disposed at an edge of the display area DA. However, the disclosure is not limited thereto, and at least a portion of each of the first spacers SPC1 adjacent to the sealing member SM may be disposed in the non-display area NDA. The second spacers SPC2 adjacent to the sealing member SM may also be substantially the same as or similar to the first spacers SPC1 adjacent to the sealing member SM.

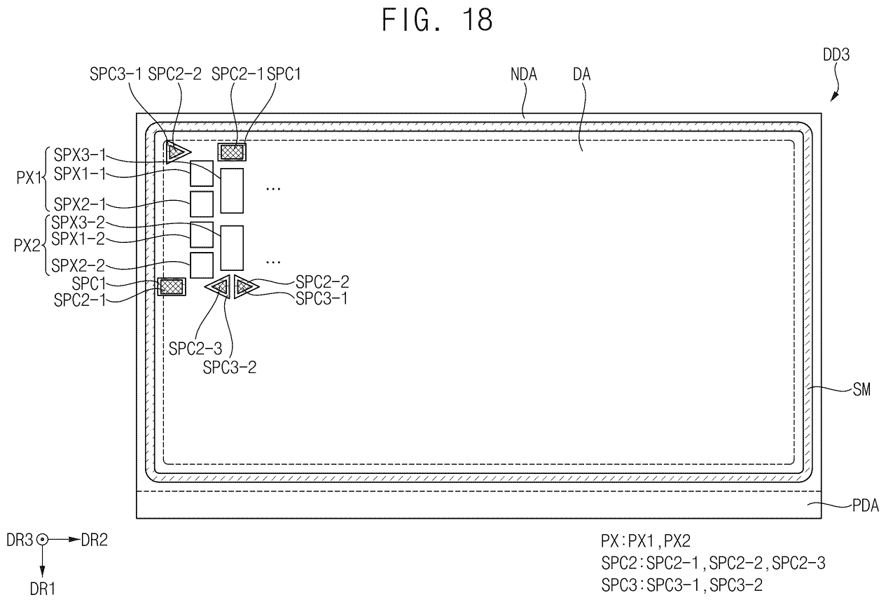

FIG. 18 is a schematic plan view illustrating a display device according to still another embodiment of the disclosure.

A display device DD3 described with reference to FIG. 18 may be substantially the same as or similar to the display device DD described with reference to FIG. 17 except for an arrangement of a first spacer SPC1, a second spacer SPC2, and a third spacer SPC3.

Hereinafter, contents overlapping with contents described with reference to FIG. 17 will be omitted or simplified.

Referring to FIG. 18, the display device DD3 may include the third spacer SPC3. The third spacer SPC3 may be formed on the first substrate SUB1. The third spacer SPC3 may be arranged on the same layer as the first spacer SPC1 and may include the same material. That is, the third spacer SPC3 may be formed through a same process as the first spacer SPC1.

Each of the first spacer SPC1, the second spacer SPC2, and the third spacer SPC3 may be spaced apart from each other in a plan view. For example, each of the first spacer SPC1, the second spacer SPC2, and the third spacer SPC3 may be spaced apart from each other in the first direction DR1 and the second direction DR2.

In an embodiment, a planar shape of a third spacer SPC3 may be different from a planar shape of a first spacer SPC1. For example, the planar shape of a third spacer SPC3 may be a triangle, and a planar shape of the first spacer SPC1 may be a square. However, a planar shape of each of the first spacer SPC1 and the third spacer SPC3 according to embodiments of the disclosure are not limited thereto.

First spacers SPC1 and third spacers SPC3 may be arranged alternately along the first direction DR1. In addition, the first spacers SPC1 and the third spacers SPC3 may be arranged alternately along the second direction DR2.

In FIG. 17, a third spacer SPC3 may be disposed, instead of a first spacer SPC1, in a portion of an area where a first spacer SPC1 is located on the first substrate SUB1.

The third spacers SPC3 may include a third-first spacer SPC3-1 and a third-second spacer SPC3-2. A planar shape of a third-first spacer SPC3-1 and a planar shape of a third-second spacer SPC3-2 may be symmetrical with respect to a straight line parallel to the first direction DR1.

The second spacer SPC2 may include a second-first spacer SPC2-1, a second-second spacer SPC2-2, and a second-third spacer SPC2-3. The second-first spacer SPC2-1 may overlap the first spacer SPC1. The second-second spacer SPC2-2 may overlap the third-first spacer SPC3-1. The second-third spacer SPC2-3 may overlap the third-second spacer SPC3-2.

Planar shapes of each of a second-first spacer SPC2-1, a second-second spacer SPC2-2, and a second-third spacer SPC2-3 may be different from each other. However, the disclosure is not limited thereto, and at least two of the planar shapes of the second-first spacer SPC2-1, the second-second spacer SPC2-2, and the second-third spacer SPC2-3 may be the same as each other.

In an embodiment, a planar shape of a second-first spacer SPC2-1 may be the same as a planar shape of a first spacer SPC1. For example, a planar shape of a second-first spacer SPC2-1 may be a square shape. However, the disclosure is not limited thereto, and a planar shape of a second-first spacer SPC2-1 may be different from a planar shape of a first spacer SPC1. In addition, a planar shape of a second-first spacer SPC2-1 may have various polygonal or circular shapes other than a square.

In an embodiment, a planar shape of a second-second spacer SPC2-2 may be the same as a planar shape of a third-first spacer SPC3-1. For example, a planar shape of a second-second spacer SPC2-2 may be a triangular shape. However, the disclosure is not limited thereto, and a planar shape of a second-second spacer SPC2-2 may be different from a planar shape of a third-first spacer SPC3-1. In addition, a planar shape of a second-second spacer SPC2-2 may have various polygonal or circular shapes other than a triangle.

In an embodiment, a planar shape of a second-third spacer SPC2-3 may be the same as a planar shape of a third-second spacer SPC3-2. For example, a planar shape of a second-third spacer SPC2-3 may be a triangular shape. However, the disclosure is not limited thereto, and a planar shape of a second-third spacer SPC2-3 may be different from a planar shape of a third-second spacer SPC3-2. In addition, a planar shape of a second-third spacer SPC2-3 may have various polygonal or circular shapes other than a triangle.

In an embodiment, a third spacer SPC3 may contact a second spacer SPC2. For example, a third-first spacer SPC3-1 may contact a second-second spacer SPC2-2. In addition, a third-second spacer SPC3-2 may contact a second-third spacer SPC2-3.

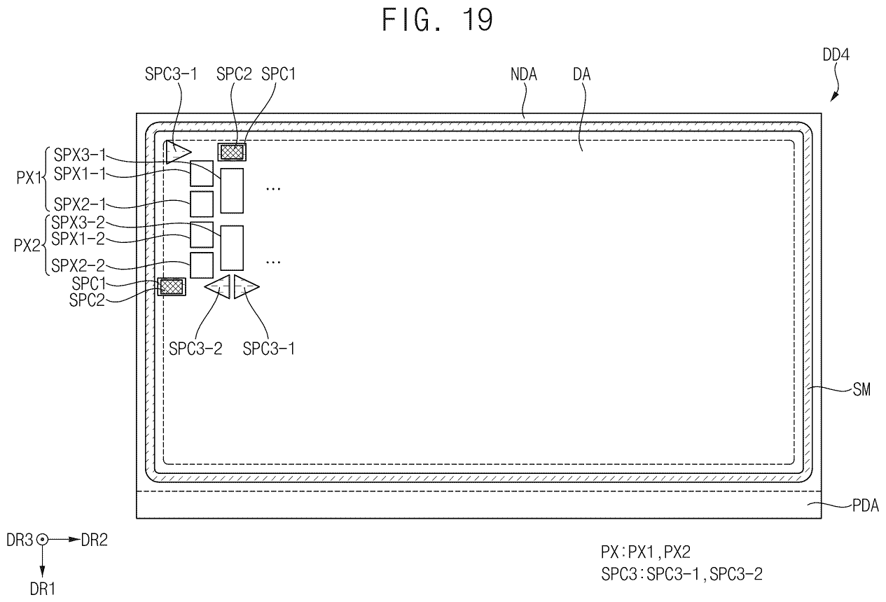

FIG. 19 is a schematic plan view illustrating a display device according to still another embodiment of the disclosure.

A display device DD4 described with reference to FIG. 19 may be substantially the same as or similar to the display device DD3 described with reference to FIG. 18 except for an arrangement of the first spacers SPC1, the second spacers SPC2, and the third spacers SPC3.

Hereinafter, contents overlapping with contents described with reference to FIG. 18 will be omitted or simplified.

Referring to FIG. 19, in an embodiment, a third spacer SPC3 may not contact the second spacer SPC2. In addition, a third spacer SPC3 may not overlap a second spacer SPC2. Second spacers SPC2 may contact first spacers SPC1. In addition, second spacers SPC2 may overlap with first spacers SPC1.

A height of the third spacers SPC3 may be substantially the same as or similar to a height of the first spacers SPC1. Accordingly, the third spacers SPC3 and the second substrate SUB2 may be spaced apart from each other. In other words, the second spacers SPC2 may not be disposed between the third spacers SPC3 and the second substrate SUB2.

The display device according to the embodiment may be applied to various electronic devices. An electronic device according to an embodiment of the present disclosure may include the display device (e.g., the display device DD of FIG. 1, the display device DD1 of FIG. 11, the display device DD2 of FIG. 17, the display device DD3 of FIG. 18, and the display device DD4 of FIG. 19) described above, and may further include modules or devices having additional functions in addition to the display device.

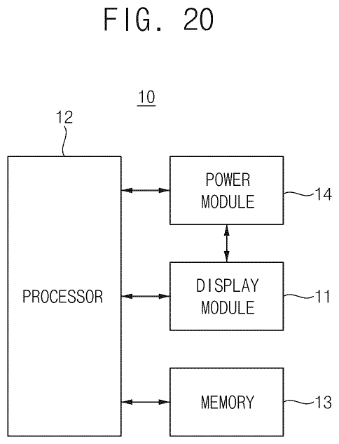

FIG. 20 is a block diagram of an electronic device according to an embodiment of the present disclosure.

Referring to FIG. 20, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other devices within the electronic device 10 except for the display device.

In an embodiment, the display module 11 included in the display device may drive based on the output image data signal and the input control signal received from the processor 12.

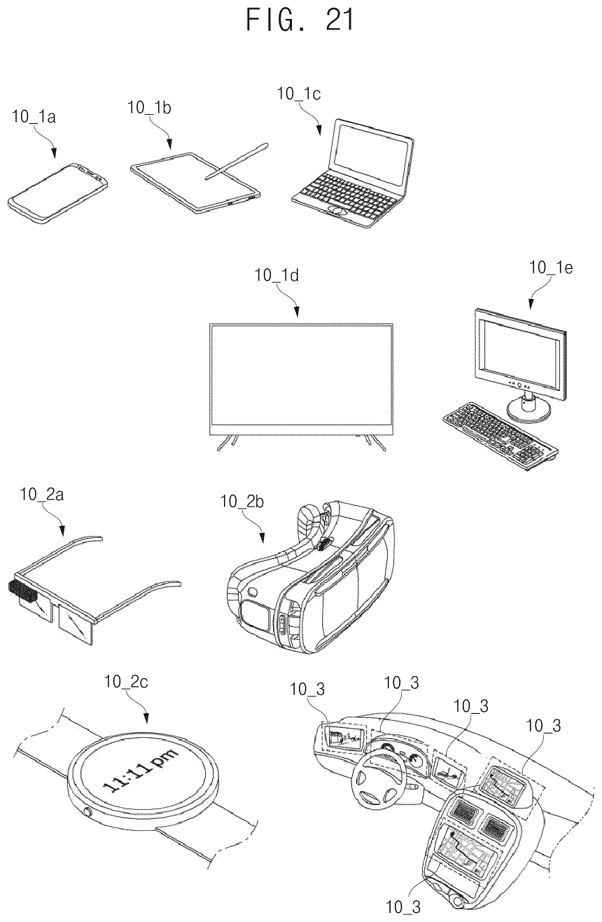

FIG. 21 is a schematic diagram of the electronic device according to various embodiments.

Referring to FIG. 21, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also a wearable electronic device including display modules such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

The device and the method according to the embodiments may be applied to a display device included in a computer, a notebook, a mobile phone, a smartphone, a smart pad, a PMP, a PDA, an MP3 player, or the like.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a first substrate;
a display element layer disposed on the first substrate, and including a plurality of pixels;
a second substrate disposed on the display element layer, and facing the first substrate;
a first spacer disposed between the display element layer and the second substrate, and extending to the display element layer; and
a second spacer disposed between the display element layer, and extending to the second substrate.

2. The display device of claim 1, wherein the second spacer extends to the first spacer.

3. The display device of claim 1, wherein the first spacer and the second spacer are spaced apart from each other in a direction parallel to the first substrate.

4. The display device of claim 3, wherein the second spacer extends to the display element layer.

5. The display device of claim 3, wherein a height of the second spacer is greater than a height of the first spacer.

6. The display device of claim 1, wherein a planar shape of the first spacer and a planar shape of the second spacer are same.

7. The display device of claim 1, wherein a planar shape of the first spacer and a planar shape of the second spacer are different.

8. The display device of claim 1, wherein the first spacer and the second spacer are disposed between pixels adjacent to each other among the plurality of the pixels.

9. The display device of claim 1, further comprising:
a third spacer disposed between multiple ones of the first spacer adjacent to each other on the first substrate, wherein
the third spacer and the first spacer include a same material.

10. The display device of claim 9, wherein the third spacer extends to the second spacer.

11. The display device of claim 9, wherein the third spacer does not extend to the second spacer.

12. The display device of claim 10, wherein a planar shape of the third spacer and a planar shape of the first spacer are different.

13. The display device of claim 1, wherein the second spacer includes an organic material.

14. The display device of claim 13, wherein the second spacer further includes an inorganic material.

15. The display device of claim 13, wherein the second spacer further includes a light-blocking material.

16. The display device of claim 1, further comprising:
a sealing member disposed on the first substrate, and surrounding at least a portion of each of the first spacer and the second spacer.

17. The display device of claim 16, wherein a height of the sealing member is greater than a sum of a height of the first spacer and a height of the second spacer.

18. A method of manufacturing a display device, a method comprising:
forming a display element layer including a plurality of pixels on a first substrate;
forming a first spacer on the display element layer;
forming a second spacer corresponding to the first substrate on a second substrate facing the first substrate; and
attaching the first substrate and the second substrate to each other.

19. The method of claim 18, wherein in the attaching of the first substrate and the second substrate to each other, the first substrate and the second substrate are attached to each other so that the first spacer and the second spacer extend to each other.

20. The method of claim 18, wherein in the attaching of the first substrate and the second substrate to each other, the first substrate and the second substrate are attached to each other so that the second spacer extends to the first substrate, and the second spacer is spaced apart from the first spacer in a direction parallel to the first substrate.

21. An electronic device comprising:
a processor configured to output an image data signal and an input control signal; and
a display device configured to drive based on the image data signal and the input control signal, and including:
a first substrate;
a display element layer disposed on the first substrate, and including a plurality of pixels;
a second substrate disposed on the display element layer, and facing the first substrate;
a first spacer disposed between the display element layer and the second substrate, and extending to the display element layer; and
a second spacer disposed between the display element layer, and extending to the second substrate.
